(19) United States
(12) Patent Application Publication
(10) Pub. No.: US 2026/0009861 A1
(43) Pub. Date: Jan. 8, 2026

(54) METHOD AND SYSTEM FOR DETECTING ABNORMAL OPERATION OF ENERGY STORAGE SYSTEM

(71) Applicant: SAMSUNG SDI CO., LTD., Yongin-si (KR)

(72) Inventor: Jeonghyup KO, Yongin-si (KR)

(21) Appl. No.: 19/001,228

(22) Filed: Dec. 24, 2024

(30) Foreign Application Priority Data
Jul. 5, 2024 (KR) 10-2024-0088729

(51) Int. Cl. G01R 31/392; G01R 31/382

(52) U.S. Cl. CPC G01R 31/392; G01R 31/382

(57) ABSTRACT

A method for detecting an abnormal operation of an energy storage system, includes: receiving operation information from the energy storage system; calculating deterioration acceleration parameters of a battery of the energy storage system based on the operation information; and detecting that the energy storage system is operating abnormally based on the calculated deterioration acceleration parameters.

### CROSS-REFERENCE TO RELATED APPLICATION

The present application claims priority to and the benefit of Korean Patent Application No. 10-2024-0088729, filed on Jul. 5, 2024, in the Korean Intellectual Property Office, the entire disclosure of which is incorporated by reference herein.

### BACKGROUND

### 1. Field

Aspects of embodiments of the present disclosure relate to a method and system for detecting an abnormal operation of an energy storage system.

### 2. Description of the Related Art

Unlike primary batteries that are not designed to be (re) charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

An energy storage system (ESS) can connect renewable energy, such as wind or solar energy, having a power output that cannot be controlled, to an existing power grid, and may charge or discharge the energy according to a power consumption pattern. In more detail, a battery energy storage system including a secondary battery may be used for stabilizing a grid voltage and frequency, and can also be linked with a renewable energy generation system with an unstable power generation amount, such as wind or solar power, to store surplus energy and supply the energy to a load by discharging the energy stored in the battery.

The above information disclosed in this Background section is for enhancement of understanding of the background of the present disclosure, and therefore, it may contain information that does not constitute related (or prior) art.

### SUMMARY

A system provider that provides an energy storage system guarantees an energy capacity that the energy storage system can supply to a customer. The guaranteed capacity may be determined by the system provider according to an initial use environment of the energy storage system. However, if the customer operates the energy storage system abnormally, the energy capacity of the energy storage system may be reduced below the guaranteed capacity.

Embodiments of the present disclosure may be directed to a method and system for detecting an abnormal operation of an energy storage system.

These and other aspects and features of the present disclosure will be described in or will be apparent from the following description of embodiments of the present disclosure.

According to one or more embodiments of the present disclosure, a method for detecting an abnormal operation of an energy storage system, includes: receiving operation information from the energy storage system; calculating deterioration acceleration parameters of a battery of the energy storage system based on the operation information; and detecting that the energy storage system is operating abnormally based on the calculated deterioration acceleration parameters.

In an embodiment, the operation information may include at least one of accumulated temperature information of the battery, excess usage time information of the battery, power information provided to the battery, state-of-charge (SOC) information during an idle period of the battery, state-of-health information of the battery, or state-of-charge range information of the battery.

In an embodiment, the calculating of the deterioration acceleration parameters may include: calculating the deterioration acceleration parameters of the battery based on deterioration data associated with the energy storage system and the operation information.

In an embodiment, the deterioration data may be determined based on a kind of the battery.

In an embodiment, the detecting that the energy storage system is operating abnormally may include: performing a simulation associated with the battery based on the operation information and the calculated deterioration acceleration parameters.

In an embodiment, a result of the simulation may include an hourly deterioration rate of the battery predicted based on the operation information.

In an embodiment, the detecting that the energy storage system is operating abnormally may be based on a result of the simulation.

In an embodiment, the method may further include: updating a guaranteed capacity of the energy storage system based on a result of the simulation.

In an embodiment, the method may further include: providing a notification in response to the detecting that the energy storage system is operating abnormally, the notification including information informing the energy storage system of an abnormal operation.

In an embodiment, the method may further include: providing analysis information in response to the detecting that the energy storage system is operating abnormally, the analysis information being associated with an operation of the energy storage system.

According to one or more embodiments of the present disclosure, a system for detecting an abnormal operation of an energy storage system, includes: a receiving part configured to receive operation information from the energy storage system; a deterioration acceleration parameter calculation part configured to calculate deterioration acceleration parameters of a battery of the energy storage system based on the operation information; and an abnormal operation detection part configured to detect that the energy storage system is operating abnormally based on the calculated deterioration acceleration parameters.

In an embodiment, the operation information may include at least one of accumulated temperature information of the battery, excess usage time information of the battery, power information provided to the battery, state-of-charge information during an idle period of the battery, state-of-health information of the battery, or state-of-charge range information of the battery.

In an embodiment, the deterioration acceleration parameter calculation part may be configured to calculate the deterioration acceleration parameters of the battery based on deterioration data associated with the energy storage system and the operation information.

In an embodiment, the deterioration data may be determined based on a kind of the battery.

In an embodiment, the abnormal operation detection part may be configured to perform a simulation associated with the battery based on the operation information and the calculated deterioration acceleration parameters.

In an embodiment, a result of the simulation may include an hourly deterioration rate of the battery predicted based on the operation information.

In an embodiment, the abnormal operation detection part may be configured to detect that the energy storage system is operating abnormally based on a result of the simulation.

In an embodiment, the system may further include: an updating part configured to update a guaranteed capacity of the energy storage system based on a result of the simulation.

In an embodiment, the system may further include: a notification providing part configured to provide a notification informing the energy storage system of an abnormal operation in response to the detecting that the energy storage system is operating abnormally.

In an embodiment, the system may further include: an analysis information providing part configured to provide analysis information associated with an operation of the energy storage system in response to the detecting that the energy storage system is operating abnormally.

According to some embodiments of the present disclosure, an abnormal operation of the energy storage system may be detected using accumulated operation information of the energy storage system. Accordingly, the system provider may prove that a decrease in energy capacity has occurred due to an abnormal operation of the energy storage system. In addition, when an abnormal operation is detected, a notification informing about the abnormal operation and analysis information on the abnormal operation may be provided, thereby allowing the administrator of the energy storage system to stably operate the energy storage system so that the capacity of the energy storage system may be improved.

These and other aspects and features of the present disclosure will be described in or will be apparent from the following description of embodiments of the present disclosure.

However, aspects and features of the present disclosure are not limited to those described above, and other aspects and features not mentioned will be clearly understood by a person skilled in the art from the detailed description, described below.

### BRIEF DESCRIPTION OF DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings.

FIG. 1 is an example of a graph showing a temperature and a state of health of each battery rack of an energy storage system.

FIG. 2 is a diagram showing an example of a process for detecting an abnormal operation by an abnormal operation detection system based on operation information received from an energy storage system according to an embodiment of the present disclosure.

FIG. 3 is a diagram showing an example of a configuration of an abnormal operation detection system according to an embodiment of the present disclosure.

FIG. 4 is a diagram showing an example of a method for calculating deterioration acceleration parameters according to an embodiment of the present disclosure.

FIG. 5 is a diagram showing an example of a method for detecting an abnormal operation of an energy storage system according to an embodiment of the present disclosure.

FIG. 6 is a diagram showing an example of deterioration data of a battery according to an embodiment of the present disclosure.

FIG. 7 is a diagram showing an example of a result of a simulation performed based on deterioration acceleration parameters of a battery according to an embodiment of the present disclosure.

FIG. 8 is a flowchart showing an example of a method for detecting an abnormal operation of an energy storage system according to an embodiment of the present disclosure.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when a layer or element is referred to as being “between” two layers, it can be the only layer between the two layers, or one or more intervening layers may also be present. It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of local patent laws.

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

As used herein, a battery rack may refer to an energy storage source including a plurality of battery modules that accommodate a plurality of secondary batteries electrically connected in series and/or in parallel with each other. In addition, as used herein, a battery rack may be used interchangeably with a battery unless the context clearly indicates otherwise.

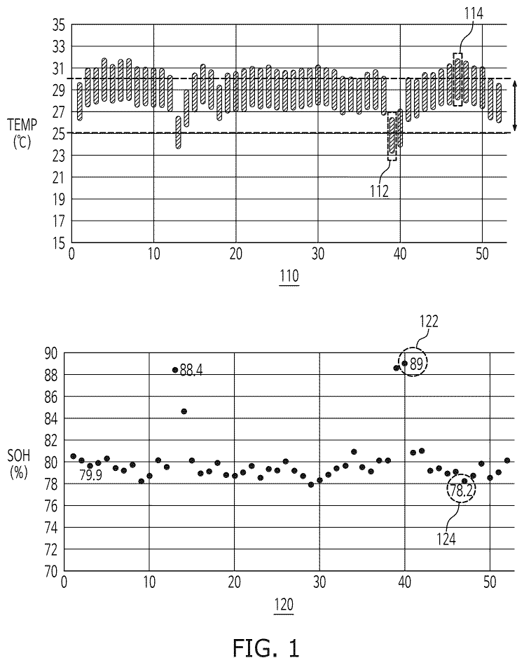

FIG. 1 is an example of a graph showing a temperature and a state of health of each battery rack of an energy storage system.

A first graph 110 shows the temperature of each battery rack of an energy storage system at a point in time (e.g., a specific or predetermined point in time). Further, a second graph 120 shows the state of health (SOH) of each battery rack of the energy storage system at a point in time (e.g., a specific or predetermined point in time).

Referring to the first graph 110, a difference between the center value of the temperature range 112 of the battery rack having the lowest temperature and the center value of the temperature range 114 of the battery rack having the highest temperature may be about 5° C. However, referring to the second graph 120, a difference between the state of health 122 of the battery rack having the lowest temperature and the state of health 124 of the battery rack having the highest temperature may be about 10.8%, which is larger than a theoretical difference in the state of health between two battery racks. In other embodiments, the temperature information for the battery rack at a point in time (e.g., a specific or predetermined point in time) may not be considered to represent all the operating periods of the energy storage system. In addition, referring to the first graph 110 and the second graph 120, it may be suggested that the customer may have operated the energy storage system abnormally, but there may be a limit in detecting an abnormal operation of the energy storage system with only the temperature information at a point in time (e.g., a specific or predetermined point in time). Hereinafter, a method for detecting an abnormal operation according to some embodiments using the operation information of the energy storage system will be described in more detail.

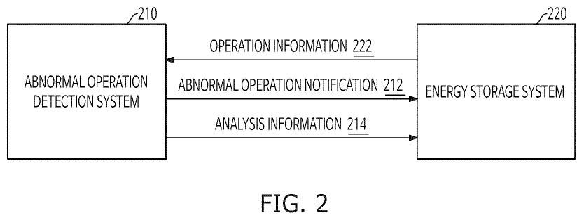

FIG. 2 is a diagram showing an example of a process for detecting an abnormal operation by an abnormal operation detection system 210 based on operation information 222 received from an energy storage system 220 according to an embodiment of the present disclosure.

In an embodiment, the abnormal operation detection system 210 may receive the operation information 222 from the energy storage system 220. The operation information 222 may include at least one of accumulated temperature information of the battery, excess usage time information of the battery, power information provided to the battery, state-of-charge (SOC) information during an idle period of the battery, state of health of the battery, or state-of-charge range information of the battery, but the present disclosure is not limited thereto.

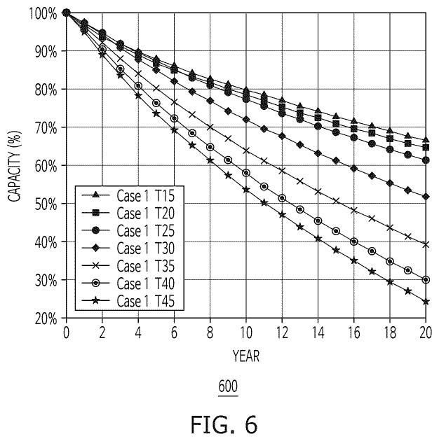

In an embodiment, the abnormal operation detection system 210 may calculate deterioration acceleration parameters of the battery of the energy storage system 220 based on the operation information 222. In more detail, the abnormal operation detection system 210 may calculate the deterioration acceleration parameters of the battery based on the deterioration data and the operation information 222 associated with the energy storage system 220. The deterioration data associated with the energy storage system 220 may be determined based on the kind of the battery used in the energy storage system 220. An example of the deterioration data will be described in more detail below with reference to FIG. 6.

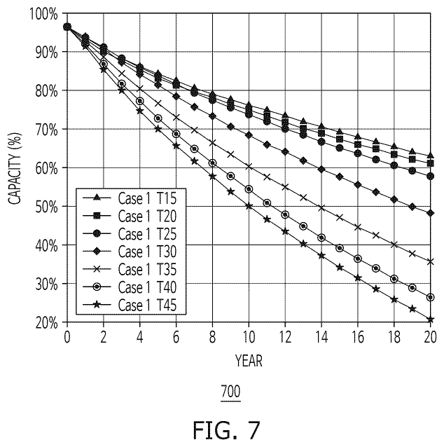

In an embodiment, the abnormal operation detection system 210 may detect whether or not the energy storage system 220 is operating abnormally based on the calculated deterioration acceleration parameters. In more detail, the abnormal operation detection system 210 may perform a simulation associated with the battery of the energy storage system 220 based on the operation information 222 and the calculated deterioration acceleration parameters. In addition, the abnormal operation detection system 210 may detect whether or not the energy storage system 220 is operating abnormally based on a result of the simulation. An example of the simulation result will be described in more detail below with reference to FIG. 7.

In an embodiment, the abnormal operation detection system 210 may provide a notification 212 informing the energy storage system 220 of an abnormal operation in response to detecting the abnormal operation. Additionally, the abnormal operation detection system 210 may provide analysis information 214 associated with the operation of the energy storage system 220 in response to detecting the abnormal operation.

An abnormal operation of the energy storage system may be detected using accumulated operation information of the energy storage system. Accordingly, the system provider may prove that a decrease in energy capacity has occurred due to an abnormal operation of the energy storage system. In addition, when an abnormal operation is detected, a notification informing about the abnormal operation and analysis information on the abnormal operation may be provided, thereby allowing the administrator of the energy storage system to stably operate the energy storage system so that the capacity of the energy storage system may be improved.

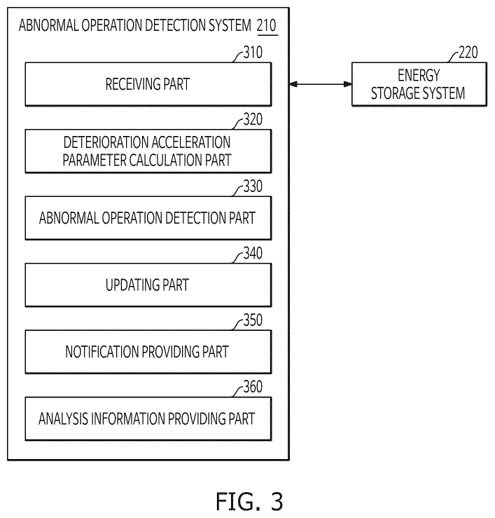

FIG. 3 is a diagram showing an example of a configuration of the abnormal operation detection system 210 according to an embodiment of the present disclosure.

In an embodiment, the abnormal operation detection system 210 may include a receiving part 310, a deterioration acceleration parameter calculation part 320, an abnormal operation detection part 330, an updating part 340, a notification providing part 350, and an analysis information providing part 360.

The receiving part 310 may receive operation information from the energy storage system 220 through a communication network or the like. In some embodiments, the operation information may include accumulated temperature information of the battery, excess usage time information of the battery, power information provided to the battery, state-of-charge information during an idle period of the battery, state of health of the battery, and state-of-charge range information of the battery. In addition, the receiving part 310 may transmit the received operation information to the deterioration acceleration parameter calculation part 320.

The deterioration acceleration parameter calculation part 320 may calculate the deterioration acceleration parameters of the battery used in the energy storage system 220 based on the operation information. In more detail, the deterioration acceleration parameter calculation part 320 may calculate the deterioration acceleration parameters of the battery based on the deterioration data and operation information associated with the energy storage system 220. The deterioration data may be determined based on the kind of the battery used in the energy storage system 220. In addition, the deterioration data may include hourly capacity data of the battery in an initial use environment of the energy storage system 220. Based on the deterioration data, a guaranteed capacity provided by the system provider may be determined.

The abnormal operation detection part 330 may detect whether or not the energy storage system 220 is operating abnormally based on the deterioration acceleration parameters calculated by the deterioration acceleration parameter calculation part 320. In more detail, the abnormal operation detection part 330 may perform a simulation associated with the battery based on the operation information and the calculated deterioration acceleration parameters. In addition, the abnormal operation detection part 330 may detect whether or not the energy storage system 220 is operating abnormally based on a simulation result. The simulation result may include the predicted battery hourly deterioration rate based on the operation information. The simulation result will be described in more detail below with reference to FIG. 7.

The updating part 340 may update the guaranteed capacity of the energy storage system 220 based on the result of the simulation performed by the abnormal operation detection part 330. In more detail, the updating part 340 may calculate the guaranteed capacity according to the detected abnormal operation of the energy storage system 220. Accordingly, the updating part 340 may update the calculated guaranteed capacity with a new guaranteed capacity of the energy storage system 220.

The notification providing part 350 may provide a notification informing about an abnormal operation in response to the abnormal operation detection part 330 detecting the abnormal operation. In this case, the notification providing part 350 may transmit a notification to the energy storage system 220 through a communication network or the like, informing that the energy storage system 220 is currently operating abnormally. The notification may be generated using at least one of text, images, or voice.

The analysis information providing part 360 may provide analysis information associated with the operation of the energy storage system 220 in response to the abnormal operation detection part 330 detecting the abnormal operation. In this case, the analysis information providing part 360 may transmit analysis information associated with the operation of the energy storage system 220 through a communication network or the like. The analysis information may include at least one of temperature information of the battery used in the energy storage system 220, power information provided to the battery, state-of-charge information during an idle period of the battery, state of health of the battery, or state-of-charge range information of the battery, but the present disclosure is not limited thereto, and for example, may also include information associated with a cause (or a potential cause) of the battery deterioration. For example, if (e.g., when) the hourly deterioration rate of the battery increases and the power provided to the energy storage system is greater than a threshold (e.g., a predetermined threshold), the analysis information providing part 360 may provide analysis information that the cause of the abnormal operation of the energy storage system may be due to excessive power supply.

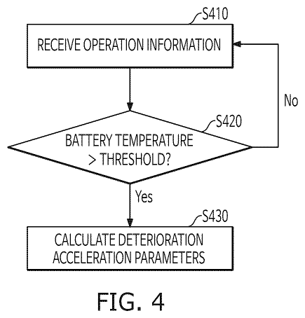

FIG. 4 is a drawing showing an example of a method for calculating deterioration acceleration parameters according to an embodiment of the present disclosure.

In an embodiment, a method for calculating deterioration acceleration parameters may be initiated by an abnormal operation detection system (e.g., 210 of FIG. 2) by receiving operation information from an energy storage system (e.g., 220) (S410). The operation information may include temperature information of a battery used in the energy storage system, excess usage time information of the battery, and other similar information. The temperature information of the battery may be accumulated temperature information of the battery. The accumulated temperature information of the battery may include temperature information of the battery at a period of time (e.g., a specific or predetermined period of time), not (e.g., instead of) temperature information of the battery at a point in time (e.g., a specific or predetermined point in time). However, the temperature information of the battery may be collected by repeatedly collecting temperature information of the battery at a point in time (e.g., a specific or predetermined point in time), and the present disclosure is not particularly limited thereto.

Thereafter, the abnormal operation detection system may compare the temperature information of the battery and a threshold (e.g., a predetermined threshold) (S420) with each other. The threshold may represent the highest temperature of the battery that is determined for a stable operation of the energy storage system. For example, the threshold may be 28° C., but the present disclosure is not limited thereto, and the threshold may be determined based on the usage environment of the energy storage system.

If (e.g., when) the temperature information of the battery is lower than the threshold (e.g., if (e.g., when) the accumulated temperature information of the battery, or in other words, the temperature of the battery at a period of time (e.g., a specific or predetermined period of time) is lower than the predetermined threshold) (e.g., NO at S420), the operation information including the temperature information of the battery may be excluded from the information for calculating the deterioration acceleration parameters. In this case (e.g., NO at S420), the abnormal operation detection system may repeatedly receive the operation information from the energy storage system (S410).

If (e.g., when) the temperature of the battery is higher than the threshold (e.g., if (e.g., when) the temperature of the battery at a point in time (e.g., a specific or predetermined point in time) of the accumulated temperature information of the battery is higher than the predetermined threshold) (e.g., YES at S420), the abnormal operation detection system may calculate the deterioration acceleration parameters of the battery of the energy storage system based on the operation information (S430). In more detail, the abnormal operation detection system may calculate the deterioration acceleration parameters of the battery based on the temperature information of the battery that is higher than the threshold (e.g., the predetermined threshold), the excess usage time information of the battery used at a temperature higher than the threshold (e.g., the predetermined threshold), and the deterioration data. The deterioration data may be determined based on the kind of the battery used in the energy storage system. The deterioration acceleration parameters may be used as information to prove that the battery has deteriorated due to the abnormal operation of the energy storage system.

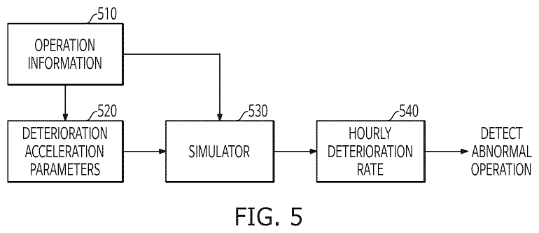

FIG. 5 is a diagram showing an example of a method for detecting an abnormal operation of an energy storage system according to an embodiment of the present disclosure.

In an embodiment, the abnormal operation detection system (e.g., 210 of FIG. 2) may receive operation information 510 from the energy storage system (e.g., 220). In addition, the abnormal operation detection system may calculate the deterioration acceleration parameters 520 of the battery of the energy storage system based on the operation information 510. In more detail, the abnormal operation detection system may calculate the battery deterioration acceleration parameters 520 based on deterioration data representing the hourly capacity of the battery of the energy storage system and the operation information 510.

In an embodiment, the abnormal operation detection system may input the operation information 510 and the deterioration acceleration parameters 520 into a simulator 530. The simulator 530 may predict and output the hourly deterioration rate 540 of the battery based on the operation information 510 and the deterioration acceleration parameters 520. Accordingly, the abnormal operation detection system may detect the abnormal operation of the energy storage system based on the hourly deterioration rate 540 of the battery. For example, when the hourly deterioration rate 540 of the battery increases compared to the theoretical hourly deterioration rate of the battery, the abnormal operation detection system may detect an abnormal operation of the energy storage system. As another example, by comparing the battery capacity on the deterioration data and the battery capacity on the simulation result for the same battery with each other, the abnormal operation detection system may detect an abnormal operation of the energy storage system.

FIG. 6 is a diagram showing an example of deterioration data of a battery according to an embodiment of the present disclosure. FIG. 7 is a diagram showing an example of a result of a simulation performed based on deterioration acceleration parameters of a battery according to an embodiment of the present disclosure.

Referring to FIG. 6, a first graph 600 is an example of deterioration data showing the capacity of a battery by time and temperature. The deterioration data may include the theoretical hourly capacity data of the battery according to the temperature of the battery in an initial use environment of the energy storage system. Referring to the first graph 600, the capacity of the battery for the same year may decrease as the temperature of the battery increases.

Referring to FIG. 7, a second graph 700 is an example of a simulation result showing the capacity of the battery by time and temperature. The simulation result may be generated based on the operation information received from the energy storage system and the deterioration acceleration parameters of the battery. Compared to the first graph 600, the capacity of the battery for the same year may be reduced due to the deterioration of the battery in the second graph 700. In other embodiments, the guaranteed capacity according to the simulation result may be lower than the initial guaranteed capacity of the system provider providing the energy storage system. Accordingly, the system provider may prove that the reduced guaranteed capacity of the energy storage system is due to an abnormal operation of the energy storage system.

In FIGS. 6 and 7, the deterioration data is displayed in increments of 5° C., but the present disclosure is not limited thereto, and deterioration data in increments of 5° C. or less may be generated using an interpolation method.

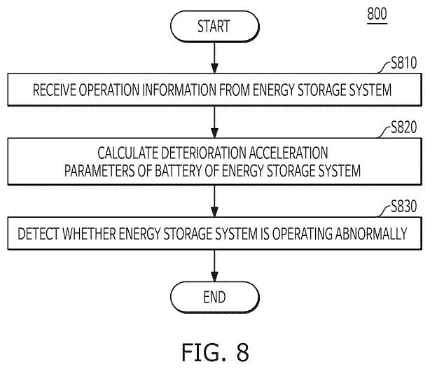

FIG. 8 is a flowchart showing an example of a method 800 for detecting an abnormal operation of an energy storage system according to an embodiment of the present disclosure.

In an embodiment, the method 800 for detecting an abnormal operation of an energy storage system may be initiated by at least one processor (e.g., at least one processor of the abnormal operation detection system) by receiving operation information from the energy storage system (S810). The operation information may include at least one of the accumulated temperature information of the battery, the excess usage time information of the battery, the power information provided to the battery, the state-of-charge information during the idle period of the battery, the state of health of the battery, or the state-of-charge range information of the battery.

Thereafter, the processor may calculate the deterioration acceleration parameters of the battery of the energy storage system based on the operation information (S820). In more detail, the processor may calculate the deterioration acceleration parameters of the battery based on the deterioration data and the operation information associated with the energy storage system. The deterioration data may be determined based on the kind of the battery.

Thereafter, the processor may detect whether or not the energy storage system is operating abnormally based on the calculated deterioration acceleration parameters (S830). In more detail, the processor may perform a simulation associated with the battery based on the operation information and the calculated deterioration acceleration parameters. In addition, the processor may detect whether or not the energy storage system is operating abnormally based on the simulation result. The simulation result may include the hourly deterioration rate of the battery predicted based on the operation information.

In an embodiment, the processor may update the guaranteed capacity of the energy storage system based on the simulation result. In addition, the processor may provide a notification informing the energy storage system of an abnormal operation in response to detecting the abnormal operation. Additionally, the processor may provide analysis information associated with the operation of the energy storage system in response to detecting the abnormal operation.

At least a portion of the method and/or components described above (e.g., the receiving part, the deterioration acceleration parameter calculation part, the abnormal operation detection part, the updating part, the notification providing part, the analysis information providing part, and the like) may be implemented as a computer program stored on a computer-readable recording medium for execution on a computer. In other embodiments, at least a portion of the method and/or the components described above may be stored on a computer-readable recording medium for execution on a computer. For example, the computer-readable recording medium may be a non-transitory computer-readable recording medium.

In an embodiment, the recording medium may be a kind of medium that continuously stores a program executable by a computer, or that temporarily stores the program for execution or download. In addition, the medium may be a variety of writing means or storage means having a single piece of hardware or a combination of several pieces of hardware, and is not limited to a medium that is directly connected to any computer system, and accordingly, may be present on a network in a distributed manner. An example of the medium includes a medium to store program instructions, including a magnetic medium, such as a hard disk, a floppy disk, and a magnetic tape, an optical medium, such as a CD-ROM and a DVD, a magnetic-optical medium, such as a floptical disk, and a ROM, a RAM, a flash memory, and/or the like. In addition, other examples of the medium may include an app store that distributes applications, a site that supplies or distributes various pieces of software, and a recording medium or a storage medium managed by a server.

The methods, operations, components, or techniques of some embodiments of the present disclosure may be implemented by various suitable means. For example, the components or techniques (e.g., the receiving part, the deterioration acceleration parameter calculation part, the abnormal operation detection part, the updating part, the notification providing part, the analysis information providing part, and the like) may be implemented in hardware, firmware, software, or a suitable combination thereof. Those having ordinary skill in the art will further appreciate that various illustrative logical blocks, modules, circuits, and algorithm steps described in connection with some embodiments of the present disclosure described herein may be implemented in electronic hardware, computer software, or suitable combinations of both. As an example, interchangeability of hardware and software, various illustrative components, blocks, modules, circuits, and steps have been described above generally in terms of their functionality. Whether such a function is implemented as hardware or software may vary according to design requirements imposed on a particular application and the overall system. Those having ordinary skill in the art may implement the described functions in varying ways for each particular application, but such implementation should not be interpreted as causing a departure from the scope of the present disclosure.

In a hardware implementation, processing units used to perform the techniques may be implemented in one or more ASICs, DSPs, digital signal processing devices (DSPDs), programmable logic devices (PLDs), field programmable gate arrays (FPGAs), processors, controllers, microcontrollers, microprocessors, electronic devices, other electronic units designed to perform the functions described in the present disclosure, computer, or a suitable combination thereof.

Accordingly, various example logic blocks, modules, and circuits described in connection with some embodiments of the present disclosure may be implemented or performed with general purpose processors, DSPs, ASICs, FPGAs or other programmable logic devices, discrete gate or transistor logic, discrete hardware components, or any suitable combination of those designed to perform the functions described herein. The general purpose processor may be a microprocessor, but in the alternative, the processor may be any related processor, controller, microcontroller, or state machine. The processor may also be implemented as a combination of computing devices, for example, a DSP and microprocessor, a plurality of microprocessors, one or more microprocessors associated with a DSP core, or any other suitable combination of the configurations.

In the implementation using firmware and/or software, the techniques may be implemented with instructions stored on a computer-readable medium, such as random-access memory (RAM), read-only memory (ROM), non-volatile random-access memory (NVRAM), programmable read-only memory (PROM), erasable programmable read-only memory (EPROM), electrically erasable PROM (EEPROM), flash memory, compact disc (CD), magnetic or optical data storage devices, and the like. The instructions may be executable by one or more processors, and may cause the processor(s) to perform certain aspects of the functions described in some embodiments of the present disclosure.

If (e.g., when) implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that may be accessed by a general purpose or special purpose computer. By way of example, and not limitation, such computer-readable media may comprise RAM, ROM, EEPROM, CD-ROM or other optical disk storage, magnetic disk storage or other magnetic storage devices, or any other medium that may be used to carry or store desired program code means in the form of instructions or data structures and that may be accessed by a general-purpose or special-purpose computer, or a general-purpose or special-purpose processor. Also, any connection is properly termed a computer-readable medium.

For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor may read information from, and/or write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

Although the examples described above have been described as utilizing aspects of the currently disclosed subject matter in one or more standalone computer systems, the present disclosure is not limited thereto, and may be implemented in conjunction with any suitable computing environment, such as a network or distributed computing environment. Furthermore, some aspects and features of embodiments of the present disclosure may be implemented in multiple processing chips or apparatuses, and storage may be similarly influenced across a plurality of apparatuses. Such apparatuses may include PCs, network servers, and portable apparatuses.

Although the present disclosure has been described above with respect to embodiments thereof, the present disclosure is not limited thereto. Various modifications and variations can be made thereto by those skilled in the art within the spirit of the present disclosure and the equivalent scope of the appended claims.

### DESCRIPTION OF SOME REFERENCE SYMBOLS

210: Abnormal operation detection system
212: Abnormal operation notification
214: Analysis information
220: Energy storage system
222: Operation information

What is claimed is:

1. A method for detecting an abnormal operation of an energy storage system, comprising:
receiving operation information from the energy storage system;
calculating deterioration acceleration parameters of a battery of the energy storage system based on the operation information; and
detecting that the energy storage system is operating abnormally based on the calculated deterioration acceleration parameters.

2. The method as claimed in claim 1, wherein the operation information comprises at least one of accumulated temperature information of the battery, excess usage time information of the battery, power information provided to the battery, state-of-charge (SOC) information during an idle period of the battery, state-of-health information of the battery, or state-of-charge range information of the battery.

3. The method as claimed in claim 1, wherein the calculating of the deterioration acceleration parameters comprises:
calculating the deterioration acceleration parameters of the battery based on deterioration data associated with the energy storage system and the operation information.

4. The method as claimed in claim 3, wherein the deterioration data is determined based on a kind of the battery.

5. The method as claimed in claim 1, wherein the detecting that the energy storage system is operating abnormally comprises:
performing a simulation associated with the battery based on the operation information and the calculated deterioration acceleration parameters.

6. The method as claimed in claim 5, wherein a result of the simulation comprises an hourly deterioration rate of the battery predicted based on the operation information.

7. The method as claimed in claim 5, wherein the detecting that the energy storage system is operating abnormally is based on a result of the simulation.

8. The method as claimed in claim 5, further comprising:
updating a guaranteed capacity of the energy storage system based on a result of the simulation.

9. The method as claimed in claim 1, further comprising:
providing a notification in response to the detecting that the energy storage system is operating abnormally, the notification comprising information informing the energy storage system of an abnormal operation.

10. The method as claimed in claim 1, further comprising:
providing analysis information in response to the detecting that the energy storage system is operating abnormally, the analysis information being associated with an operation of the energy storage system.

11. A system for detecting an abnormal operation of an energy storage system, comprising:
a receiving part configured to receive operation information from the energy storage system;
a deterioration acceleration parameter calculation part configured to calculate deterioration acceleration parameters of a battery of the energy storage system based on the operation information; and
an abnormal operation detection part configured to detect that the energy storage system is operating abnormally based on the calculated deterioration acceleration parameters.

12. The system as claimed in claim 11, wherein the operation information comprises at least one of accumulated temperature information of the battery, excess usage time information of the battery, power information provided to the battery, state-of-charge information during an idle period of the battery, state-of-health information of the battery, or state-of-charge range information of the battery.

13. The system as claimed in claim 11, wherein the deterioration acceleration parameter calculation part is configured to calculate the deterioration acceleration parameters of the battery based on deterioration data associated with the energy storage system and the operation information.

14. The system as claimed in claim 13, wherein the deterioration data is determined based on a kind of the battery.

15. The system as claimed in claim 11, wherein the abnormal operation detection part is configured to perform a simulation associated with the battery based on the operation information and the calculated deterioration acceleration parameters.

16. The system as claimed in claim 15, wherein a result of the simulation comprises an hourly deterioration rate of the battery predicted based on the operation information.

17. The system as claimed in claim 15, wherein the abnormal operation detection part is configured to detect that the energy storage system is operating abnormally based on a result of the simulation.

18. The system as claimed in claim 15, further comprising:
an updating part configured to update a guaranteed capacity of the energy storage system based on a result of the simulation.

19. The system as claimed in claim 11, further comprising:
a notification providing part configured to provide a notification informing the energy storage system of an abnormal operation in response to the detecting that the energy storage system is operating abnormally.

20. The system as claimed in claim 11, further comprising:
an analysis information providing part configured to provide analysis information associated with an operation of the energy storage system in response to the detecting that the energy storage system is operating abnormally.
